(19) United States
(12) Patent Application Publication
(10) Pub. No.: US 2007/0200571 A1
(43) Pub. Date: Aug. 30, 2007

(54) Verifying individual probe contact using shared tester channels

(76) Inventors: Kevin Quinn, Richmond, VT (US); Peter Thwaite, Burlington, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/354,969

(22) Filed: Feb. 16, 2006

(51) Int. Cl. G01R 31/02

(52) U.S. Cl. 324/754

(57) ABSTRACT

Verifying good electrical contact between pads of multiple circuit dies and a probe card or test device, where the driver channels of the test device or probe card device are connected in parallel to corresponding contacts on the circuit dies. Each of a plurality of test device or probe card device driver channels are connected to a corresponding one of a plurality of contacts on each of the plurality of circuit dies such that each test device driver channel is shared among a corresponding contact on each of said plurality of circuit dies. Logic circuitry on each chip connects each of the plurality of contacts to at least one designated contact to output from the device via said at least one designated contact a voltage that corresponds to a voltage at one of said plurality of contacts when a voltage is applied to said one of said plurality of contacts. A voltage is applied at the test device driver channel and the voltage on the designated contact of each of the circuit dies that is coupled to said plurality of contacts on the circuit die is evaluated to determine whether contact is made between the test device driver channel pin or terminal (either directly or via or probe card) and the corresponding contact on each of said plurality of circuit dies.

### BACKGROUND OF THE INVENTION

The present invention is directed to semiconductor devices, and more particularly to verifying electrical contact between individual pads on an unpackaged integrated circuit device (or individual pins or solder balls on a packaged integrate circuit device) and a probe card or test device.

When manufacturing semiconductor integrated circuit (IC) devices in large volumes, it is desirable to conduct tests on as many of the so-called IC “dies” or “chips” in parallel as possible to reduce the overall time, and thus cost, required for testing. A test device is connected to each of the chips (either directly or via a probe card) and supplies test commands to the chips to conduct various tests.

There are a limited number of channels on a test device. A “channel” is basically all of the electronics required to get a signal from the test device to the integrated circuit device(s) under test. Generally speaking, there are three types of test device channels that can be shared: power supply, input/output (I/O) and driver channels. Each type of test device channel needs to be handled differently. A test device interfaces with an integrated circuit device either directly or indirectly by way of a probe card. The number of instances of the electronics in the test device is the physical limitation on the number of available channels. Typically one pin or terminal on the probe card would be assigned to each channel. One type of shared driver configuration involves assigning each channel to several pins (e.g., on a probe card) so that each pin serves the same test function. The maximum number of pins then depends on the strength of the driver in each of the channels.

Before tests can be conducted, it is necessary to first determine that there is electrical contact made between the test or probe card device and the corresponding pads on each of the dies or chips that are being tested in parallel. One problem with sharing the test device driver channel across multiple chips concerns verifying good contact (open-circuit and short-circuit testing) between the test device and the pads on each of the chips. As shown in FIG. 1, a test device 10 electrically interfaces via a probe card or cable 20 having some resistance R to a contact (pin, pad or solder ball) 30 of a chip. There is a diode D between the contact 30 and ground. The standard continuity test involves forcing a negative current to the contact 30 and measuring the resulting voltage after contact to the pad is attempted. If good contact is made, then the voltage observed at the contact 30 should be one diode threshold voltage drop, e.g., approximately −0.4 V. When there is a short on the channel between the test device 10 and the contact 30, the voltage observed will be ground or a few mV higher. If no contact is made on the channel between the test device 10 and the contact 30 (e.g., and open-circuit), then the voltage observed will be the limit value that was set by the test device, e.g., −3.0 V or −5.0 V.

FIG. 2 illustrates a shared driver channel between a test device 10 and contacts 30(1) to 30(N) on each of N plurality of chips. The standard contact measurement or continuity test is the same as described above in conjunction with FIG. 1. If only one pad makes good electrical contact with the test device, then as to the test device 10, it will appear that all pads are making good electrical contact, even if in fact some or all of the other pads do not make good electrical contact.

During a production test of a plurality of chips in parallel, a test operator executes a continuity test as described above to make sure the test setup is correct. Because the test device driver channels are shared in the manner shown in FIG. 2, it is not possible to individually test all pads on all chips for open-circuit and short-circuit conditions, and the resulting false positive contact tests may cause improper functional testing, causing unnecessary yield loss or delaying production because the wafers will need to be tested again.

### SUMMARY OF THE INVENTION

Briefly, a method for performing a continuity test between test device driver channels and contacts (pads of an unpackaged circuit die or pins or solder balls of a packaged integrated circuit) of a plurality of integrated circuit dies in parallel. Each of a plurality of test driver channels are connected (either directly or via a probe card device) to a corresponding one of a plurality of contacts on each of the plurality of circuit dies such that each test device driver channel is shared among a corresponding contact on each of said plurality of circuit dies. A voltage is applied at the test device driver channel and the voltage on a designated contact of each of the circuit dies that is coupled to said plurality of contacts on the circuit die is evaluated to determine whether contact is made between the test device (or probe card) driver channel and the corresponding contact on each of said plurality of circuit dies.

In addition, a semiconductor integrated circuit device having circuitry to facilitate continuity testing with a test device in parallel with other similar integrated circuits is provided. The integrated circuit device comprises a plurality of contacts that are associated with various functions of the integrated circuit device; at least one designated contact through which data may be input to, or output from, the integrated circuit device; and logic circuitry that connects each of the plurality of contacts to said at least designated contact to output from the device via said at least one designated contact a voltage that corresponds to a voltage at one of said plurality of contacts when a voltage is applied to said one of said plurality of contacts.

### BRIEF DESCRIPTION OF THE DRAWINGS

FIG. 1 is a block diagram of a prior art testing configuration for performing a continuity test on a single pad of an integrated circuit device.

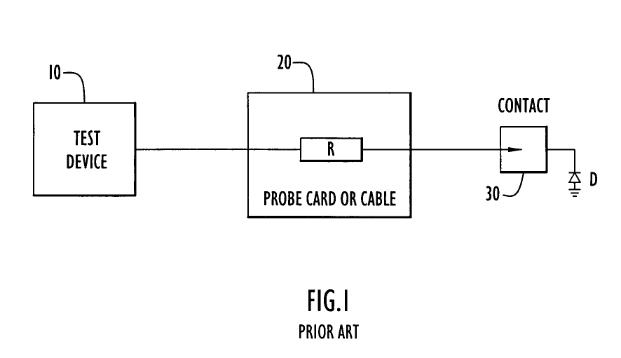

FIG. 2 is a block diagram of a prior art testing configuration for performing a continuity test on multiple pads in parallel.

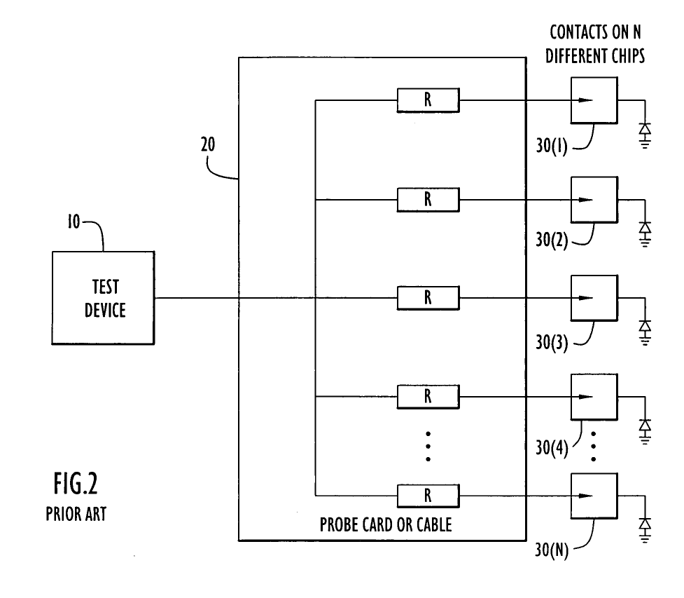

FIG. 3 is a block diagram of a semiconductor integrated circuit device according to an embodiment of the present invention.

FIGS. 4A and 4B illustrate a flow chart depicting a continuity test mode for testing each of a plurality of pads on a plurality of integrated circuit devices according to an embodiment of the present invention.

FIG. 5 is a block diagram of a semiconductor integrated circuit device according to another embodiment of the present invention.

FIG. 6 is a block diagram of a semiconductor integrated circuit device according to still another embodiment of the present invention.

FIG. 7 is a schematic diagram of a pull-up bleeder circuit used in the circuit configurations of FIGS. 3 and 5 according to an embodiment of the present invention.

FIG. 8 is a schematic diagram of a pull-down bleeder circuit used in the circuit configurations of FIGS. 3 and 5 according to an embodiment of the present invention.

### DETAILED DESCRIPTION

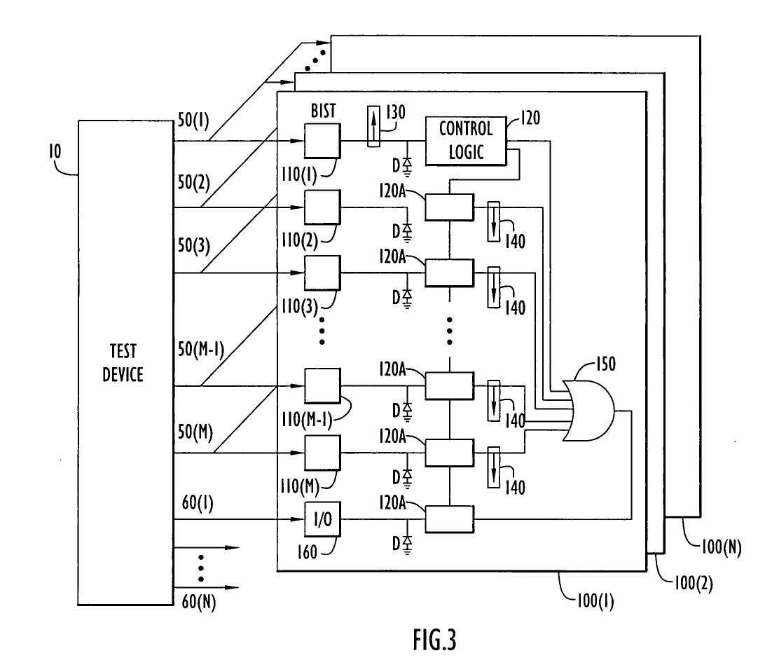

Turning to FIG. 3, an integrated circuit device is shown that incorporates circuitry that facilitates continuity testing with a test device or probe card device in parallel with other similar integrated circuits, according to an embodiment of the invention. The test device 10 connects to a plurality of semiconductor integrated circuit devices 100(1) to 1 00(N) in parallel, either directly or via a probe card (not shown). The devices 100(1) to 100(N) may be part of a wafer of unpackaged integrated circuit dies whereby connection to the circuit dies is made by way of individual contact pads. Alternatively, the devices 100(1) to 1 00(N) may be packaged integrated circuit devices where connection to the circuit devices is made by way of individual contact pins or solder balls. In general, the term “contact” is used hereinafter to refer to a contact pad or other contact surface on an unpackaged integrated circuit as well as a pin or solder ball on a packaged integrated circuit.

There are a plurality of shared driver channels 50(1) to 50(M) between the test device and corresponding individual contacts on each of the integrated circuit devices 100(1) to 100(N). The integrated circuit devices may be any type of device, such as a memory device, processor, or other application specific integrated circuits. Shown in FIG. 3 is the enabling circuitry on one of the chips, 100(1), but it is to be understood that each of the other chips 100(2) to 1 00(N) include similar circuitry. Each of the chips comprises a plurality of contacts (pads, pins or solder balls) 110(1) to 110(M) that are associated with certain functions of the chip. There are control logic blocks 120 and 120A between a corresponding contact 110(1) to 110(M) and OR gate logic shown in FIG. 3 in the form of a single multiple input OR gate 150. The control logic blocks 120 and 120A are responsive to a certain voltage condition on at least one of the contacts, such as a built-in-self-test (BIST) contact 110(1 ) to cause the chip to enter a continuity test mode for the contacts 110(1) to 110(M). There is a pull-up bleeder circuit 130 connected between the BIST contact 110(1) and the control logic 120. Between each of the other contacts 110(2) to 110(M) and the OR gate 150 there is a pull-down bleeder circuit 140. There are also a plurality of designated channels, such as input/output (I/O) channels 60(1) to 60(N), between the test device and the chips 100(1) to 100(N) that are not shared. That is, there is at least one designated contact, such as an I/O pad (pin or solder ball) 160, on each chip 100(1) to 100(N) that is connected to a dedicated I/O terminal on the test device 10 (or corresponding pin on a probe card) via a corresponding one of the I/O channels 60(1) to 60(N). While the unshared channels 60(1) to 60(N) are shown as I/O channels, it should be understood that they may be any individual designated pin, pad or solder ball on the integrated circuit that is not shared and is not limited to an I/O pin, pad or solder ball.

The control logic blocks 120 and 120A are provided to make the continuity test mode transparent to an end user of the chips. Thus, the continuity test mode is entered only when a particular voltage condition is applied to a particular one of the pads on the chip, which in the example described herein, is the BIST contact 110(1). Thus, the control logic block 120, when enabled, connects the BIST contact 110(1) to the OR gate 150. Similarly, the control logic blocks 120A, when enabled, connect their associated contact 110(2) to 110(M) to the OR gate 150.

The pull-up bleeder circuit 130 serves to force the voltage associated with BIST contact 110(1) “High” in a default state so that the continuity test mode described herein is invoked only when the voltage on BIST contact 110(1) is forced “Low”. Conversely, the pull-down bleeder circuit 140 associated with each of the other contact 110(2) to 110(M) forces the voltage on these contacts to be “Low” in a default state.

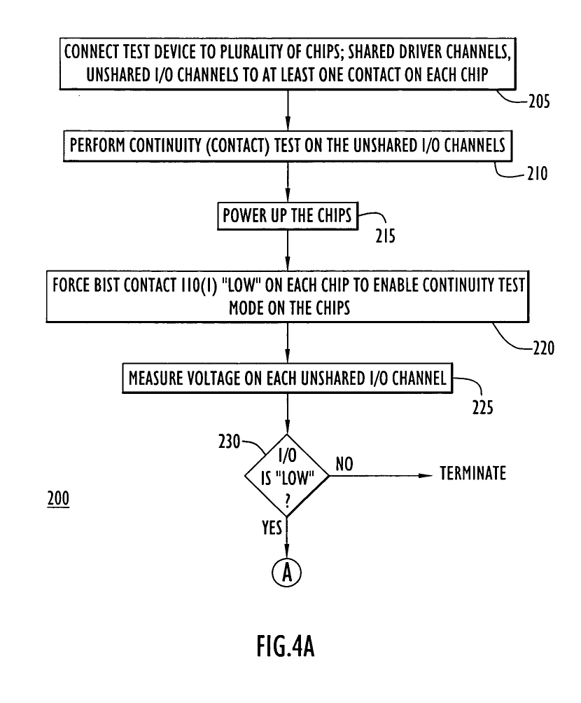

Turning to FIGS. 4A and 4B, with continued reference to FIG. 3, a procedure 200 for a shared driver continuity test mode will be described. At 205, the test device or probe card is interfaced to a plurality of chips or dies to be tested in parallel such that there are shared driver channels across the plurality of chips or dies but there is an unshared I/O channel between at least one contact on each chip or die and the test device or probe card. Next, at 210, a continuity test is performed on each of the unshared I/O channels to be sure these unshared I/O channels are working properly. The subsequent steps of the continuity test for the shared driver channels rely on the fact that the unshared I/O channels to at least one I/O contact on each chip or die is operating normally.

Assuming the unshared I/O channels pass the continuity test, then at 215, each of the chips or dies is powered up. Next, at 220, the continuity test mode for the chips is invoked by applying a “Low” voltage to the driver channel 50(1) so that the BIST contact 110(1) on each of the chips is pulled low. The control logic 120 on each chip interprets this condition to automatically put the chip into the continuity test mode, and to couple each contact 110(1) to 10(M) to the OR gate 150. The voltages on the unshared I/O channels 60(1) to 60(N) are measured to be sure that the voltage on the BIST pad 110(1) is “Low”, indicating that contact to BIST contact 110(1) is good. If any one of the voltages on the unshared I/O channels is not “Low”, then contact to BIST contact 110(1) is not made and the procedure 200 terminates.

If in 225, the voltages on all of the unshared I/O channels are “Low”, then the procedure continues to 235 in which a “Low” voltage is applied by the test device on all the shared driver channels 50(1) to 50(M), and the contact measurement loop depicted at 240-255 commences.

At 240, a “High” voltage is applied to a shared driver channel, e.g., driver channel is 50(2), associated with contact 110(2) on each chip 100(1) to 100(N). At 245, the voltage on the unshared I/O channels 60(1) to 60(M) is measured to verify that the voltage on contact 110(2) is “High” for each of the chips. Next, at 250, a “Low” voltage is applied to that same shared driver channel and verification is made at 255 that the voltage on the unshared I/O channels 60(1) to 60(M) is also “Low”.

As depicted at 260 and 265, the contact test loop of 240-255 is repeated for each contact by moving to the next unshared I/O channel 50(3), 50(4) to test continuity with contact 110(3), then 110(4) and so on. A chip is said to pass the contact test if all the contact test loops pass, otherwise it is said to fail the contact test if any of the contact test loops fails. The process can be repeated again to verify that the same results occur.

The advantage of this shared driver channel continuity testing configuration is that it is possible to determine which particular contact on each of the chips is not making contact with the test or probe card, yet still perform the continuity tests in parallel across a plurality of circuit dies.

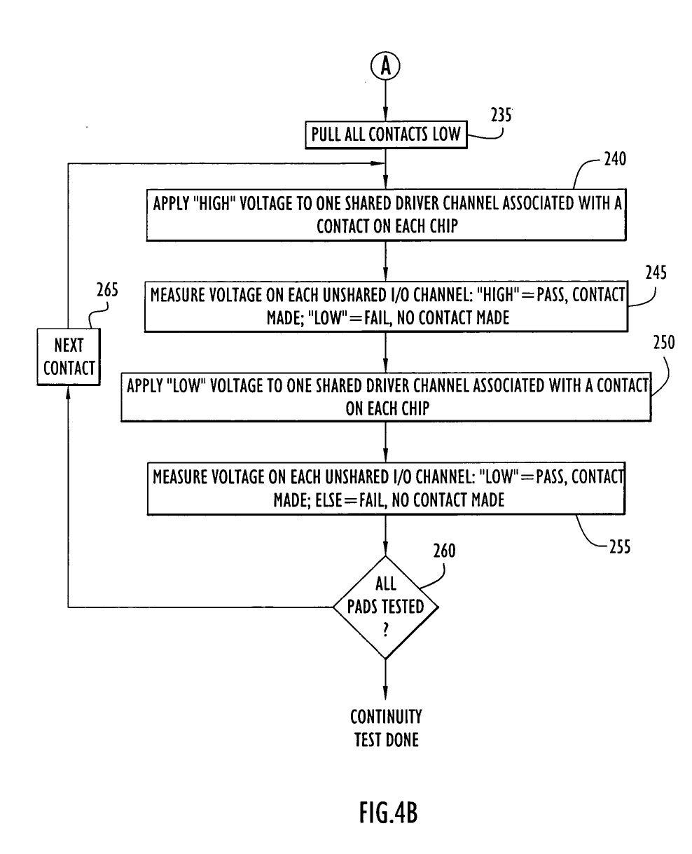

FIG. 5 illustrates circuitry inside a chip 100′(1) according to another embodiment of the invention. In this embodiment, instead of a single OR gate 150 having many inputs as shown in FIG. 3, there are several two-input OR gates 150(1) to 150(M) that are connected in a cascaded fashion. Specifically, connected to one input of each of the OR gates 150(1) to 150(M) is ground. The other input of OR gate 150(1) is connected to an output of the control logic block 120. The output of OR gate 150(1) is connected to a first input of OR gate 150(2). The other input of OR gate 150(2) is connected to the pull-down bleeder circuit 140 associated with contact 110(2). The output of OR gate 150(2) is connected to a first input of OR gate 150(3) as is the output of the pull-down bleeder circuit 140 associated with contact 110(3). The advantage of this embodiment is that only one writing channel (i.e., physical space on the die) is required to connect the OR gates in series, rather than having a single OR gate with many inputs that need to be routed from all of the contacts to be tested on the die.

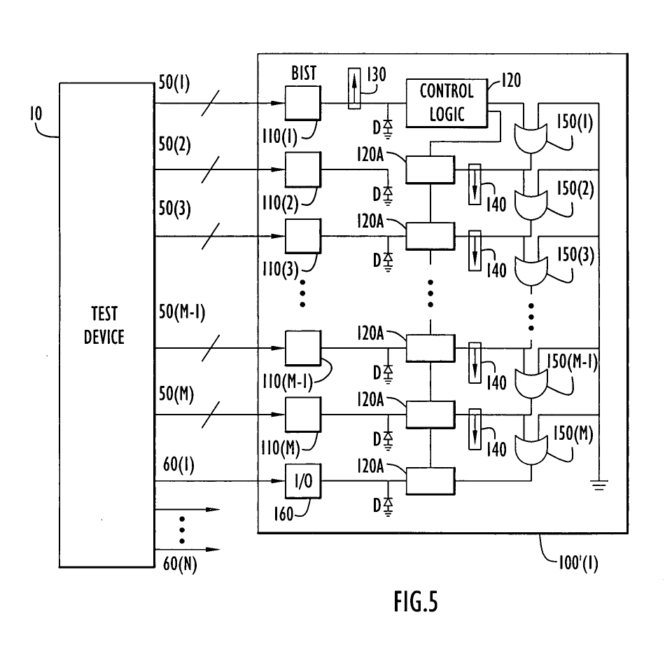

FIG. 6 illustrates circuitry inside a chip 100″(1) according to still another embodiment of the invention. In this embodiment, there are no OR gates at all. Instead, each of the contacts of a chip or die is connected together and an evaluation is made of the voltage directly by leaving the contacts that are not being tested floating. In this case, the voltage measured will correspond directly to the voltage applied to a single contact that is not left floating. The procedure shown in FIGS. 4A and 4B would be modified to reflect this difference.

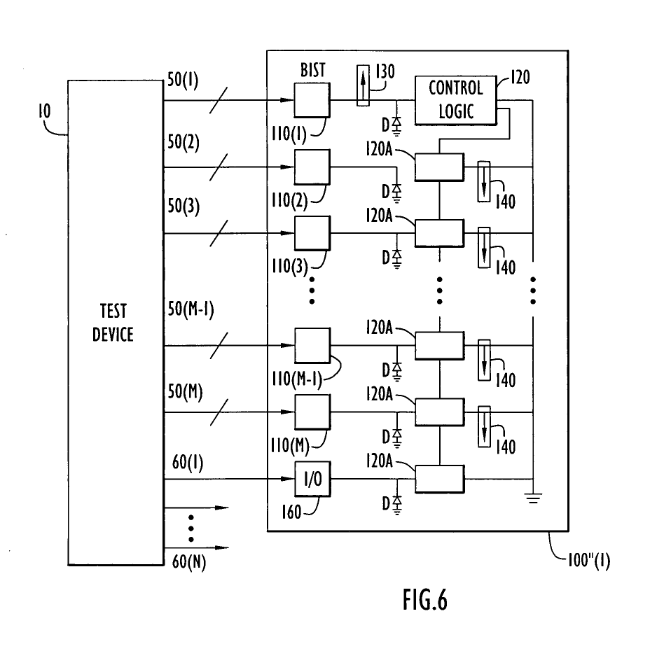

Turning to FIG. 7, an example of a pull-up bleeder circuit 130 is shown. The pull-up bleeder circuit 130 comprises a plurality of P-FET transistors Q1, Q2, . . . , Q(S). The gates of each of the transistors are connected to ground, Vss. The source of transistor Q1 is connected to the positive voltage supply, Vdd, and the drain of transistor Q1 is connected to the source of transistor Q2 and so on. The drain of transistor Q(S) is connected to the node that is to be pulled-up to Vdd, which in the case of the present invention, is the BIST contact 110(1).

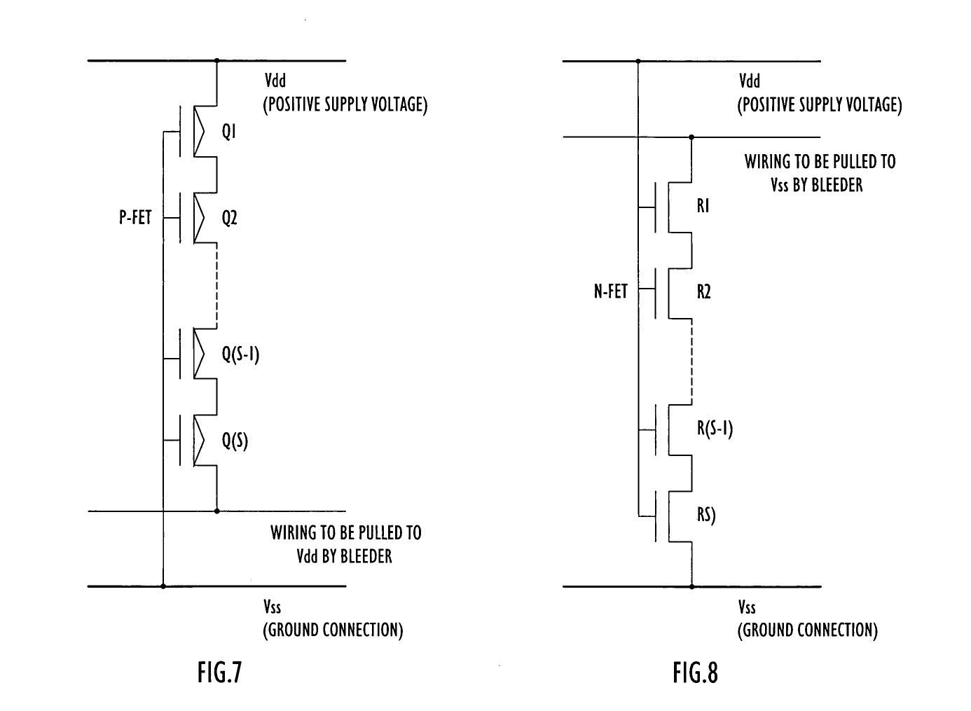

FIG. 8 illustrates an example of a pull-down bleeder circuit 140. The pull-down bleeder circuit comprises a plurality of N-FET transistors R1, R2, . . . , R(S). The gates of each of the transistors are connected to the positively supply voltage, Vdd. The drain of transistor R1 is connected to the node that is to be pulled-down to ground, which in the case of the present invention is each of pads 110(2) to 110(M). The drain of transistor R1 is connected to the source of transistor R2 and so on. The source of transistor R(S) is connected to ground, Vss.

The system and methods described herein may be embodied in other specific forms without departing from the spirit or essential characteristics thereof. The foregoing embodiments are therefore to be considered in all respects illustrative and not meant to be limiting.

What is claimed is:

1. A method for performing a continuity test between a test device or probe card and individual contacts of a plurality of circuit dies in parallel, comprising:
a. connecting each of a plurality of test device driver channels to a corresponding one of a plurality of contacts on each of said plurality of circuit dies such that each test device driver channel is shared among a corresponding contact on each of said plurality of circuit dies;
b. connecting a designated contact on each of the plurality of circuit dies to the plurality of contacts;
c. connecting each of a plurality of input/output channels of said test device to the designated contact of a corresponding one of said plurality of circuit dies such that each input/output channel of the test device is connected to the designated contact of a different one of said plurality of circuit dies; and
d. evaluating the voltage on the designated contacts of each of the plurality of circuit dies when a voltage is applied at the test device driver channel to determine whether contact is made between the test device driver channel and the corresponding contact on each of said plurality of circuit dies.

2. The method of claim 1, wherein (d) evaluating further comprises (i) applying a “high” voltage at the test device driver channel and determining whether there is a “high” voltage at each input/output channel of the test device, and (ii) applying a “low” voltage at the test device driver channel and determining whether there is a “low” voltage at each input/output channel of the test device.

3. The method of claim 2, wherein (d) evaluating is sequentially performed for each of the plurality of test device driver channels to verify continuity on each of the plurality of contacts of said plurality of circuit dies in parallel.

4. The method of claim 1, wherein (d) evaluating further comprises determining that a contact on a circuit die passes the continuity test if the voltage at the designated contact for the corresponding circuit die follows the voltage applied at the test device driver channel.

5. A method for performing a continuity test between a test device and contacts of a plurality of circuit dies in parallel, comprising:
a. connecting each of a plurality of test device driver channels to a corresponding one of a plurality of contacts on each of said plurality of circuit dies such that each test device driver channel is shared among a corresponding contact on each of said plurality of circuit dies; and
b. evaluating the voltage on designated contact that is coupled to said plurality of contacts of each of said plurality of circuit dies when a voltage is applied at the test device driver channel to determine whether contact is made between the test device driver channel and the corresponding contact on each of said plurality of circuit dies in parallel.

6. The method of claim 5, and further comprising connecting each of a plurality of test device input/output channels to the designated contact of a corresponding one of said plurality of circuit dies such that each input/output channel of the test device is connected to the designated contact of a different one of said plurality of circuit dies.

7. The method of claim 6, wherein (b) evaluating further comprises (i) applying a “high” voltage at the test device driver channel and determining whether there is a “high” voltage at each input/output channel of the test device, and (ii) applying a “low” voltage at the test device driver channel and determining whether there is a “low” voltage at each input/output channel of the test device.

8. The method of claim 6, and further comprising performing a continuity test on said designated contact of each of said plurality of circuit dies prior said (b) evaluating.

9. The method of claim 5, and further comprising applying a voltage at one of said plurality of test device driver channels to a particular one of said plurality of contacts on each of said plurality circuit dies to enable a control circuit on each of said circuit dies to initiate a continuity test mode on said plurality of integrated circuit dies.

10. A semiconductor integrated circuit device, comprising:
a. a plurality of contacts that are associated with various functions of the integrated circuit device;
b. at least one designated contact through which data may be input to, or output from, the integrated circuit device; and
c. logic circuitry that connects each of the plurality of contacts to said at least one designated contact to output from the device via said at least one designated contact a voltage that corresponds to a voltage at one of said plurality of contacts when a voltage is applied to said one of said plurality of contacts.

11. The device of claim 10, wherein the logic circuitry comprises an OR gate having a plurality of inputs and an output, each of the plurality of OR gate inputs being connected to a corresponding one of said plurality of contacts, and the OR gate output being connected to said at least one designated contact.

12. The device of claim 10, wherein the logic circuitry comprises a plurality of OR gates each having first and second inputs and an output, the first input of each of the plurality of OR gates being connected to ground, a second input of each of said plurality of OR gates being connected to a corresponding one of said plurality of contacts, and wherein the outputs of one of said OR gates is connected to said designated contact and the outputs of each of the other OR gates is tied to the second input of the OR gate associated with an adjacent contact.

13. The device of claim 10, and further comprising a control circuit connected to at least one of said plurality of contacts, the control circuit being responsive to a particular voltage condition on said one of said plurality of contacts to enter a continuity test mode to determine whether electrical contact is made between each of said plurality of contacts and a corresponding terminal of a test device or pin of a probe card device.

14. The device of claim 13, and further comprising a pull-down bleeder circuit connected between the logic circuitry and a corresponding one of all but said at least one of said plurality contacts, and a pull-up bleeder circuit connected between said at least one of said plurality of contacts and said control circuit.

15. In combination, a test device and a plurality of semiconductor integrated circuit devices according to claim 10, wherein said test device comprises a plurality of test device driver channels that connect to a corresponding one of said plurality of contacts on each of said plurality of integrated circuit devices such that each test device driver channel is shared among a corresponding contact on each of said plurality of integrated circuits, a plurality of input/output channels that are connected to the at least one designated contact of a corresponding one of said plurality of integrated circuits such that each input/output channel is connected to the at least one designated contact of a different one of said plurality of integrated circuits, wherein the test device sequentially applies a voltage from one of said plurality of driver channels to perform a continuity test on a corresponding contact of each of said plurality of integrated circuits in parallel.

16. A semiconductor integrated circuit device, comprising:
a. a plurality of contacts that are associated with various functions of the integrated circuit device;
b. at least one designated contact through which data may be input to, or output from, the integrated circuit device; and
c. means for connecting each of the plurality of contacts to said at least one designated contact to output from the device via said at least one designated contact a voltage that corresponds to a voltage at one of said plurality of contacts when a voltage is applied to said one of said plurality of contacts.

17. The device of claim 16, and further comprising control means connected to at least one of said plurality of contacts and responsive to a particular voltage condition on said one of said plurality of contacts to enter a continuity test mode to determine whether electrical contact is made between each of said plurality of contacts and a corresponding terminal of a test device or pin of a probe card device.

18. The device of claim 16, wherein said means for connecting comprises an OR gate having a plurality of inputs and an output, each of the plurality of OR gate inputs being connected to a corresponding one of said plurality of contacts, and the OR gate output being connected to said at least one designated contact.

19. The device of claim 16, wherein said means for connecting comprises a plurality of OR gates each having first and second inputs and an output, the first input of each of the plurality of OR gates being connected to ground, a second input of each of said plurality of OR gates being connected to a corresponding one of said plurality of contacts, and wherein the outputs of one of said OR gates is connected to said at least one designated contact and the outputs of each of the other OR gates is tied to the second input of the OR gate associated with an adjacent contact.
